(19) United States
(12) Patent Application Publication
(10) Pub. No.: US 2014/0278169 A1
(43) Pub. Date: Sep. 18, 2014

(54) APPARATUS FOR PREDICTING STATE OF HEALTH OF BATTERY PACK BY USING DISCRETE WAVELET TRANSFORM

(71) Applicant: SAMSUNG SDI CO., LTD., Yongin-si (KR)

(72) Inventor: Jong-Hoon Kim, Yongin-si (KR)

(21) Appl. No.: 13/924,368

(22) Filed: Jun. 21, 2013

Related U.S. Application Data
(60) Provisional application No. 61/778,146, filed on Mar. 12, 2013.

(51) Int. Cl. G01R 31/36

(52) U.S. Cl. CPC G01R 31/362
USPC 702/63

(57) ABSTRACT

A method of predicting a state of health (SOH) of a battery pack is provided. The method includes: obtaining at least one of charging voltage data or discharging voltage data for each of a plurality of selected cells of the battery pack; wavelet transforming the at least one of charging voltage data or discharging voltage data to obtain low frequency component voltage data and high frequency component voltage data; calculating respective standard deviations of at least two from among the at least one of charging voltage data or discharging voltage data, the low frequency component voltage data, and the high frequency component voltage data; and predicting the SOH of the battery pack based on the calculated standard deviations.

### CROSS-REFERENCE TO RELATED APPLICATION

This application claims priority to and the benefit of U.S. Provisional Application No. 61/778,146, filed on Mar. 12, 2013 in the U.S. Patent and Trademark Office, the entire content of which is incorporated herein by reference.

### BACKGROUND

1. Field

Aspects of one or more embodiments of the present invention relate to an apparatus for predicting a state of health (SOH) of a battery pack by using a discrete wavelet transform.

2. Description of the Related Art

Along with an increase in serious problems such as environmental destruction, resource exhaustion, and the like, interest in systems capable of storing energy and efficiently utilizing the stored energy is increasing. In addition, interest in new renewable energy capable of generating energy without generating pollution is also increasing. An energy storage system, which is a system for linking together an existing system to a power generation system and a battery system, the power generating system for generating the new renewable energy and the battery system for storing electrical energy, has been actively researched and developed to meet modern environmental changes.

In the energy storage system, the battery system stores the new renewable energy generated by the power generation system and the electrical energy provided from the existing system, and provides the stored electrical energy to a load or the existing system. In the battery system, estimation of the remaining capacity of a battery is an important function. Accurate calculation of the remaining capacity of the battery to control charging and discharging of the battery enables efficient operation of the energy storage system.

Regarding the remaining capacity of the battery, resistance and capacity deteriorate according to a use environment or a period of use. This results in a decrease in the available capacity or an increase in the resistance. This, in turn, leads to a decrease in a state of health (SOH), that is, the performance of the battery when compared to an initial manufacturing stage of the battery. Due to the decrease in the SOH of the battery, the estimation of the remaining capacity of the battery is inaccurate when compared to the initial manufacturing stage of the battery.

When the estimation of the remaining capacity of the battery is inaccurate, operating efficiency of the energy storage system decreases, and a risky status may develop. For example, when a calculated remaining capacity is 30% even though an actual remaining capacity is 80%, a vehicle controller may determine that charging is necessary, thereby overcharging the battery. On the other hand, when the calculated remaining capacity is 80% even though the actual remaining capacity is 80%, the battery may be overdischarged. Such overcharging or overdischarging of the battery may cause fire or explosion of the battery. Thus, for an efficient operation and risk prevention with respect to the battery system, the SOH of the battery should be accurately estimated.

There exist various SOH estimating methods. A first method is directly measuring the remaining capacity by fully charging and fully discharging the battery. While this determines the SOH of the battery, the first method is not efficient due to the fully charging and fully discharging of the battery that are part of the method.

A second method of SOH estimation is to directly connect a hardware load of a predetermined frequency to the battery and then measure the impedance of the load. The second method is also not efficient due to factors such as the overhead of the circuit configuring portion of the method, errors, durability, costs of sensors, and the like.

A third method is to acquire current data and voltage data for a predetermined period and determine an indirect impedance and the remaining capacity from the acquired data. The third method, however, suffers from low accuracy and is very complicated due to inherent nonlinearity and disturbances. In addition, while a magnitude of a resistance component increases as the battery ages, a correlation between the remaining capacity and the resistance component does not always exist.

Thus, it would be beneficial if the SOH of a battery could be accurately predicted based on easily obtainable data such as the battery pack voltage.

### SUMMARY

In a first embodiment of the present invention, a method of predicting a state of health (SOH) of a battery pack is provided. The method includes: obtaining at least one of charging voltage data or discharging voltage data for each of a plurality of selected cells of the battery pack; wavelet transforming the at least one of charging voltage data or discharging voltage data to obtain low frequency component voltage data and high frequency component voltage data; calculating respective standard deviations of at least two from among the at least one of charging voltage data or discharging voltage data, the low frequency component voltage data, and the high frequency component voltage data; and predicting the SOH of the battery pack based on the calculated standard deviations.

In one embodiment, the obtaining of the at least one of charging voltage data or discharging voltage data includes: detecting cell voltages of the selected cells with a cell voltage detection unit over a period of time to generate analog voltage values; and converting the analog voltage values to digital voltage values to generate the at least one of charging voltage data or discharging voltage data.

In one embodiment, the cell voltage detection unit includes a memory for storing the at least one of charging voltage data or discharging voltage data of the selected cells.

In one embodiment, the method further includes calculating a corresponding at least two from among a charging and discharging SOH component from the calculated standard deviations of the at least one of charging voltage data or discharging voltage data, a low frequency SOH component from the calculated standard deviations of the low frequency component voltage data, and a high frequency SOH component from the calculated standard deviations of the high frequency component voltage data.

In one embodiment, the predicting of the SOH comprises calculating a weighted average of the calculated SOH components.

In one embodiment, the calculating of the respective standard deviations comprises calculating respective standard deviations of at least two from among the at least one of charging voltage data or discharging voltage data for each of the selected cells, the low frequency component voltage data for each of the selected cells, and the high frequency component voltage data for each of the selected cells.

In one embodiment, the calculating of the respective standard deviations further comprises calculating respective standard deviations of a corresponding at least two from among the calculated standard deviations of the at least one of charging voltage data or discharging voltage data for each of the selected cells, the calculated standard deviations of the low frequency component voltage data for each of the selected cells, and the calculated standard deviations of the high frequency component voltage data for each of the selected cells.

In one embodiment, the calculating of the respective standard deviations includes: calculating the respective standard deviations using voltage data corresponding to an initial period of time to generate initial calculated standard deviations; and calculating the respective standard deviations using voltage data corresponding to a period of interest to generate interested calculated standard deviations.

In one embodiment, the initial period of time includes a period of time when the battery pack initially starts, and the method further comprises storing the generated initial calculated standard deviations in a non-transitory storage device.

In one embodiment, the method further includes calculating a corresponding at least two from among a charging and discharging SOH component from the initial calculated standard deviations and the interested calculated standard deviations of the at least one of charging voltage data or discharging voltage data, a low frequency SOH component from the initial calculated standard deviations and the interested calculated standard deviations of the low frequency component voltage data, and a high frequency SOH component from the initial calculated standard deviations and the interested calculated standard deviations of the high frequency component voltage data.

In one embodiment, the predicting of the SOH includes calculating a weighted average of the calculated SOH components.

In one embodiment, a corresponding at least two from among the calculating of the charging and discharging SOH component further includes calculating the charging and discharging SOH component from a charging and discharging coefficient, the calculating of the low frequency SOH component further includes calculating the low frequency SOH component from a low frequency coefficient, and the calculating of the high frequency SOH component further includes calculating the high frequency SOH component from a high frequency coefficient.

In one embodiment, the coefficients are calculated from empirical data over a plurality of battery packs that are comparable to the battery pack.

In one embodiment, the wavelet transforming of the at least one of charging voltage data or discharging voltage data includes: converting the at least one of charging voltage data or discharging voltage data to first level low frequency component voltage data and first level high frequency component voltage data; converting the first level low frequency component voltage data to second level low frequency component voltage data and second level high frequency component voltage data; and converting the second level low frequency component voltage data to third level low frequency component voltage data and third level high frequency component voltage data.

In one embodiment, the wavelet transforming of the at least one of charging voltage data or discharging voltage data includes performing multi-resolution analysis of a discrete wavelet transform of the at least one of charging voltage data or discharging voltage data for each of the selected cells.

In one embodiment, the performing of the multi-resolution analysis includes performing the multi-resolution analysis up to a jth level, j is a natural number greater than 2, the low frequency component voltage data is low frequency component voltage data of the jth level, and the high frequency component voltage data is high frequency component voltage data of the jth level.

In one embodiment, the low frequency component voltage data of the jth level corresponds to a first frequency band comprising frequencies lower than a first frequency, and the high frequency component voltage data of the jth level corresponds to a second frequency band comprising frequencies higher than the first frequency and lower than double the first frequency.

In another embodiment of the present invention, an apparatus for predicting a state of health (SOH) of a battery pack is provided. The apparatus includes: a processor; and a non-transitory storage device, wherein the storage device has instructions stored thereon that, when executed by the processor, causes the processor to perform the method of the first embodiment described above.

In yet another embodiment of the present invention, a state of health (SOH) prediction apparatus configured to predict an SOH of a battery pack coupled to the SOH prediction apparatus is provided. The SOH prediction apparatus includes: a voltage detection unit configured to generate at least one of charging voltage data or discharging voltage data for each of a plurality of selected cells of the battery pack collected over a period of time; a discrete wavelet transform (DWT) unit configured to extract low frequency component voltage data and high frequency component voltage data by performing multi-resolution analysis of the DWT for the at least one of charging voltage data or discharging voltage data; a first statistics processing unit configured to generate respective first order standard deviations of at least two from among the at least one of charging voltage data or discharging voltage data, the low frequency component voltage data, and the high frequency component voltage data; a second statistics processing unit configured to generate respective second order standard deviations from the generated first order standard deviations; and an SOH prediction unit configured to predict the SOH of the battery pack from the generated second order standard deviations.

### BRIEF DESCRIPTION OF THE DRAWINGS

The above and other features and aspects of the present invention will become more apparent by describing in detail embodiments thereof with reference to the attached drawings in which:

FIG. 1 is a schematic block diagram of a state of health (SOH) prediction apparatus of a battery pack according to an embodiment of the present invention;

FIG. 2 illustrates a scale function and a wavelet function;

FIG. 3 is a schematic block diagram for describing a discrete wavelet transform in terms of filtering;

FIG. 4 illustrates coefficients of a low-pass filter and a high-pass filter;

FIG. 5 is a block diagram for describing a process of decomposing voltage data by performing discrete wavelet transform multi-resolution analysis;

FIG. 6 illustrates down-sampling;

FIG. 7 illustrates a frequency band of approximate voltage data of an nth level and frequency bands of detailed voltage data of first to nth levels;

FIG. 8A is a graph of cell voltage data V(x) of an arbitrary one of a plurality of battery cells included in a battery pack;

FIG. 8B illustrates graphs of low frequency component data A1(x) to A5(x) of first to fifth levels, which are extracted from the cell voltage data V(x) by performing discrete wavelet transform multi-resolution analysis on the cell voltage data of FIG. 8A;

FIG. 8C illustrates graphs of high frequency component data D1(x) to D5(x) of the first to fifth levels, which are extracted from the cell voltage data V(x) by performing discrete wavelet transform multi-resolution analysis on the cell voltage data of FIG. 8A;

FIG. 9A is a graph of cell voltage data V of 14 battery cells included in a battery pack;

FIG. 9B is a graph of low frequency component data A5 of the fifth level, which is extracted by performing discrete wavelet transform multi-resolution analysis on each of the cell voltage data V of FIG. 9A;

FIG. 9C is a graph of high frequency component data D5 of the fifth level, which is extracted by performing discrete wavelet transform multi-resolution analysis on each of the cell voltage data V of FIG. 9A; and

FIGS. 10A to 10I are graphs showing cell voltage data V of 14 battery cells included in second to tenth battery packs P2 to P10, graphs showing low frequency component data A5 of the fifth level, and graphs showing high frequency component data D5 of the fifth level.

### DETAILED DESCRIPTION

Hereinafter, the present invention will be described in detail by explaining embodiments of the invention with reference to the attached drawings. The present invention may, however, be embodied in many different forms and should not be construed as being limited to the embodiments set forth herein; rather, these embodiments are provided to more fully convey concepts of the invention to one of ordinary skill in the art, as defined by the claims and their equivalents.

The terminology used in the application is for describing specific embodiments and is not intended to limit the inventive concepts. An expression in the singular includes an expression in the plural unless they are clearly different from each other in context. In the application, it should be understood that terms such as ‘include’ and ‘have’ are used to indicate the existence of an implemented feature, number, step, operation, element, part, or a combination thereof without excluding in advance the possibility of the existence or addition of one or more other features, numbers, steps, operations, elements, parts, or combinations thereof. Although terms such as ‘first’ and ‘second’ can be used to describe various elements, the elements are not limited thereby. The terms may be used to distinguish a certain element from another element without necessarily implying an order between the elements.

Reference will now be made in detail to embodiments, examples of which are illustrated in the accompanying drawings, wherein like reference numerals refer to like or corresponding elements throughout, and thus their repetitive description will not be repeated. In this regard, the described embodiments may have different forms and should not be construed as being limited to the descriptions set forth herein. Accordingly, the embodiments are merely described below, by referring to the figures, to explain aspects of the present invention. As used herein, the term “and/or” includes any and all combinations of one or more of the associated listed items.

FIG. 1 is a schematic block diagram of a state of health (SOH) prediction apparatus 10 for a battery pack P1, according to an embodiment of the present invention.

Referring to FIG. 1, the SOH prediction apparatus 10 is connected to the battery pack P1 and includes a voltage detection unit 110, a discrete wavelet transform (DWT) unit 120, a first statistics processing unit 130, a second statistics processing unit 140, an initial value storage unit 150, a coefficient storage unit 160, and an SOH prediction unit 170.

The battery pack P1 includes a plurality of battery cells capable of receiving electrical energy from the outside, storing the electrical energy, and supplying the stored electrical energy to the outside. In one embodiment, the battery cells in the battery pack P1 are connected in series to each other, while in another embodiment, they are connected in parallel to each other. In still another embodiment, the battery cells in the battery pack P1 are connected to each other in a combination of a series connection and a parallel connection.

In one embodiment, the battery pack P1 is included in a battery system. In one embodiment, the battery system includes the battery pack P1, a protection circuit for protecting the battery pack P1, and a battery management system (BMS) for controlling the protection circuit to protect the battery pack P1. For example, in one embodiment, in case of a flow of overcurrent or overdischarging, the BMS opens a switch of the protection circuit to open terminals of the battery pack P1. In one embodiment, the BMS collects various kinds of data, such as voltage data, current data, and temperature data, by monitoring states, e.g., a temperature, a voltage, a current, and the like, of the battery cells in the battery pack P1. In one embodiment, the BMS performs a cell balancing operation of the battery cells according to the collected data and an internal algorithm. In one embodiment, the SOH prediction apparatus 10 is included in the BMS.

In one embodiment, the battery system including the battery pack P1 is a portion of an energy storage system for stably supplying power to a load by linking to a power generation system and a grid system. In one embodiment, the energy storage system stores electrical energy generated by the power generation system in a battery. In one embodiment, the energy storage system supplies the generated electrical energy to the grid system. In one embodiment, the energy storage system supplies the stored electrical energy to the grid system. In one embodiment, the energy storage systems stores electrical energy supplied from the grid system in the battery. In addition, in one embodiment, the energy storage system supplies the electrical energy generated by the power generation system or the electrical energy stored in the battery to the load. To this end, in some embodiments, the energy storage system includes a power conversion system (PCS), the battery system, a first switch, and a second switch.

In some embodiments, the PCS includes power conversion devices, such as an inverter, a converter, a rectifier, and the like, and a general controller to convert electrical energy provided from the power generation system, the grid system, and the battery system to a proper form of electrical energy, and to supply the converted electrical energy to a location as required. In one embodiment, the general controller monitors states of the power generation system, the grid system, the battery system, and the load, and controls the first switch, the second switch, the battery system, and the power conversion devices according to an algorithm or a command of an operator. In one embodiment, the SOH prediction apparatus 10 is included in the general controller of the energy storage system.

Although only one battery pack P1 is shown in FIG. 1, in other respective embodiments, the battery pack P1 is connected in series, in parallel, or in combinations of one or more series connections and one or more parallel connections to other battery packs to store or supply electrical energy of a higher voltage or a larger capacity.

In FIG. 1, the voltage detection unit 110 generates first to nth cell voltage data V₁, V₂, V₃, . . . , Vₙ by receiving first to nth cell voltages v₁, v₂, v₃, . . . , vₙ from respective first to nth battery cells of the battery pack P1, and digitizing the received first to nth cell voltages v₁, v₂, v₃, . . . , vₙ. In further detail, the first cell voltage data V₁ is generated by digitizing the first cell voltage v₁ of the first battery cell, and the second cell voltage data V₂ is generated by digitizing the second cell voltage v₂ of the second battery cell. Continuing in this manner, the nth cell voltage data Vₙ is generated by digitizing the nth cell voltage vₙ of the nth battery cell.

In one embodiment, the first to nth cell voltages v₁, v₂, v₃, . . . , vₙ are cell voltages of all the battery cells included in the battery pack P1. In another embodiment, the first to nth cell voltages v₁, v₂, v₃, . . . , vₙ are cell voltages of n battery cells selected from among all the battery cells included in the battery pack P1. The first to nth cell voltages v₁, v₂, v₃, . . . , vₙ have analog values varying over a time t, where t is an interval of time. In one embodiment, the same current profile is applied to the battery cells included in the battery pack P1.

The first to nth cell voltage data V₁, V₂, V₃, . . . , Vₙ have digital values generated by digitizing the first to nth cell voltages v₁, v₂, v₃, . . . , vₙ, respectively, over the (interval of) time t, and are defined according to a discrete time x. The discrete time x corresponds to the (interval of) time t. In one embodiment, the voltage detection unit 110 includes a plurality of analog-digital converters (ADCs) for converting the first to nth analog cell voltages v₁, v₂, v₃, . . . , vₙ to the first to nth digital cell voltage data V_{I}, V₂, V₃, . . . , Vₙ.

In one embodiment, the voltage detection unit 110 stores the first to nth cell voltage data V₁, V₂, V₃, . . . , Vₙ used to predict an SOH of the battery pack P1. To this end, in one embodiment, the voltage detection unit 110 further includes a memory device.

In respective embodiments, the first to nth cell voltage data V₁, V₂, V₃, . . . , Vₙ used to predict the SOH of the battery pack P1 is data of the first to nth cell voltages v₁, v₂, v₃, . . . , vₙ for a duration selected from, for example, several minutes to tens of hours. For example, in one embodiment, the voltage detection unit 110 stores the first to nth cell voltage data V₁, V₂, V₃, . . . , Vₙ obtained by digitizing the first to nth analog cell voltages v₁, v₂, v₃, . . . , vₙ for 24 hours. The data collection period is only illustrative and in other respective embodiments, is a shorter time, such as 1 hour, or a longer time, such as 48 hours, than 24 hours.

In addition, in respective embodiments, a sampling rate of the voltage detection unit 110 is set to between 1 and 600 samples per minute. However, these sampling rates do not limit the present invention. In other respective embodiments, the sampling rate is less than 1 sample per minute or greater than 600 samples per minute. In one embodiment, the voltage detection unit 110 provides the first to nth cell voltage data V₁, V₂, V₃, . . . , Vₙ collected for a set or predetermined time to the DWT unit 120.

In FIG. 1, the DWT unit 120 generates first to nth low frequency component data Aⱼ₁, Aⱼ₂, Aⱼ₃, . . . , Aⱼₙ of a jth level and first to nth high frequency component data Dⱼ₁, Dⱼ₂, Dⱼ₃, . . . , Dⱼₙ of the jth level by performing discrete wavelet transform multi-resolution analysis on the first to nth cell voltage data V₁, V₂, V₃, . . . , Vₙ provided from the voltage detection unit 110. In the current embodiment, it is assumed that the multi-resolution analysis of the discrete wavelet transform is performed up to the jth level, where j is a natural number greater than 2. The first to nth low frequency component data Aⱼ₁, Aⱼ₂, Aⱼ₃, . . . , Aⱼₙ of the jth level and the first to nth high frequency component data Dⱼ₁, Dⱼ₂, Dⱼ₃, . . . , Dⱼₙ of the jth level also have digital values defined according to the (discrete) time x.

Although it has been described in the current embodiment that the first to nth low frequency component data Aⱼ₁, Aⱼ₂, Aⱼ₃, . . . , Aⱼₙ and the first to nth high frequency component data Dⱼ₁, Dⱼ₂, Dⱼ₃, . . . , Dⱼₙ of a final level, i.e., the jth level, are extracted, in other respective embodiments, first to nth low frequency component data Aⱼ₁, Aⱼ₂, Aⱼ₃, . . . , Aⱼₙ and first to nth high frequency component data Dⱼ₁, Dⱼ₂, Dⱼ₃, . . . , Dⱼₙ of an intermediate level not the final level, i.e., a kth level, may be extracted by the DWT unit 120, where k is a natural number that is greater than 1 and less than j.

In one embodiment, the DWT unit 120 extracts the first low frequency component data Aⱼ₁ of the jth level and the first high frequency component data Dⱼ₁ of the jth level by performing the multi-resolution analysis of the discrete wavelet transform for the first cell voltage data V₁. In addition, the DWT unit 120 extracts the second low frequency component data Aⱼ₂ of the jth level and the second high frequency component data Dⱼ₂ of the jth level by performing the discrete wavelet transform multi-resolution analysis on the second cell voltage data V₂. Continuing in this manner, the DWT unit 120 extracts the nth low frequency component data Aⱼₙ of the jth level and the nth high frequency component data Dⱼₙ of the jth level by performing the multi-resolution analysis of the discrete wavelet transform for the nth cell voltage data Vₙ. The discrete wavelet transform will be described in further detail below with reference to FIGS. 2 to 7.

In FIG. 1, the first statistics processing unit 130 generates first to nth cell voltage standard deviations σ(V₁), σ(V₂), σ(V₃), σ(Vₙ), first to nth low frequency component standard deviations σ(Aⱼ₁), σ(Aⱼ₂), σ(Aⱼ₃), . . . , σ(Aⱼₙ), and first to nth high frequency component standard deviations σ(Dⱼ₁), σ(Dⱼ₂), σ(Dⱼ₃), . . . , σ(Dⱼₙ) by receiving the first to nth cell voltage data V₁, V₂, V₃, . . . , Vₙ, the first to nth low frequency component data Aⱼ₁, Aⱼ₂, Aⱼ₃, . . . , Aⱼₙ of the jth level, and the first to nth high frequency component data Dⱼ₁, Dⱼ₂, Dⱼ₃, . . . , Dⱼₙ of the jth level and calculating a (first order) standard deviation for each of them.

In one embodiment, the first statistics processing unit 130 generates the first to nth cell voltage standard deviations σ(V₁), σ(V₂), σ(V₃), . . . , σ(Vₙ) by calculating a standard deviation for each of the first to nth cell voltage data V₁, V₂, V₃, . . . , Vₙ for a set or predetermined period or interval of time. For example, in one embodiment, the first cell voltage standard deviation σ(V₁) has a standard deviation value of the first cell voltage data V₁ having a digital value varying over the (interval of) time t. In addition, the second cell voltage standard deviation σ(V₂) has a standard deviation value of the second cell voltage data V₂ having a digital value varying over the (interval of) time t. Continuing in this manner, the nth cell voltage standard deviation σ(Vₙ) has a standard deviation value of the nth cell voltage data Vₙ having a digital value varying over the (interval of) time t.

A small value of a kth cell voltage standard deviation σ(Vₖ) indicates that a variation of a kth cell voltage vₖ of a kth battery cell for the set or predetermined period of time is small, and a large value of the kth cell voltage standard deviation σ(Vₖ) indicates that a variation of the kth cell voltage vₖ of the kth battery cell for the set or predetermined period of time is large. Herein, the kth battery cell indicates an arbitrary battery cell in the battery pack P1.

In addition, in one embodiment, when the kth cell voltage standard deviation σ(Vₖ) is greater than the first cell voltage standard deviation σ(V₁), it indicates that an internal impedance of the kth battery cell is greater than an internal impedance of the first battery cell since the same current profile is applied to the kth battery cell and the first battery cell. Herein, the first battery cell indicates an arbitrary battery cell other than the kth battery cell from among the battery cells in the battery pack P1.

In one embodiment, the first statistics processing unit 130 generates the first to nth low frequency component standard deviations σ(Aⱼ₁), σ(Aⱼ₂), σ(Aⱼ₃), . . . , σ(Aⱼₙ) by calculating a standard deviation for each of the first to nth low frequency component data Aⱼ₁, Aⱼ₂, Aⱼ₃, . . . , Aⱼₙ of the jth level for the set or predetermined period of time. For example, in one embodiment, the first low frequency component standard deviation σ(Aⱼ₁) has a standard deviation value of the first low frequency component data Aⱼ₁ of the jth level of the first battery cell, which has a digital value varying over the (interval of) time t. In addition, second low frequency component standard deviation σ(Aⱼ₂) has a standard deviation value of the second low frequency component data Aⱼ₂ of the jth level of the second battery cell, which has a digital value varying over the (interval of) time t. Continuing in this manner, the nth low frequency component standard deviation σ(Aⱼₙ) has a standard deviation value of the nth low frequency component data Aⱼₙ of the jth level of the nth battery cell, which has a digital value varying over the (interval of) time t.

A small value of a kth low frequency component standard deviation σ(Aⱼₖ) indicates that a variation of a component in a first frequency band of a kth cell voltage vₖ of a kth battery cell for the set or predetermined period of time is small, and a large value of the kth low frequency component standard deviation σ(Aⱼₖ) indicates that a variation of the component in the first frequency band of the kth cell voltage vₖ of the kth battery cell for the set or predetermined period of time is large. Herein, the kth battery cell indicates an arbitrary battery cell in the battery pack P1. The component in the first frequency band of the kth cell voltage vₖ of the kth battery cell corresponds to the jth low frequency component data Aⱼₖ of the jth level extracted from kth cell voltage data Vₖ of the kth battery cell, and may be obtained by removing high frequency component noise from the kth cell voltage vₖ of the kth battery cell (for example, by applying a discrete wavelet transform as described in further detail below).

In one embodiment, the first statistics processing unit 130 generates the first to nth high frequency component standard deviations σ(Dⱼ₁), σ(Dⱼ₂), σ(Dⱼ₃), . . . , σ(Dⱼₙ) by calculating a standard deviation for each of the first to nth high frequency component data Dⱼ₁, Dⱼ₂, Dⱼ₃, . . . , Dⱼₙ of the jth level for the set or predetermined period of time. A kth high frequency component standard deviation σ(Dⱼₖ) has a standard deviation value of a kth high frequency component data Dⱼₖ of the jth level of the kth battery cell, which has a digital value varying along the (interval of) time t. Herein, the kth battery cell indicates an arbitrary battery cell in the battery pack P1.

A small value of the kth high frequency component standard deviation σ(Dⱼₖ) indicates that a variation of a component in a second frequency band of a kth cell voltage vₖ of the kth battery cell for the set or predetermined period of time is small, and a large value of the kth high frequency component standard deviation σ(Dⱼₖ) indicates that a variation of the component in the second frequency band of the kth cell voltage vₖ of the kth battery cell for the set or predetermined period of time is large. The component in the second frequency band of the kth cell voltage vₖ of the kth battery cell corresponds to the jth high frequency component data Dⱼₖ of the jth level extracted from kth cell voltage data Vₖ of the kth battery cell. For example, in one embodiment, the first frequency band indicates a frequency band lower than an arbitrary frequency fₛ, and the second frequency band indicates a frequency band higher than the arbitrary frequency fₛ and lower than double the arbitrary frequency fₛ.

In addition, in one embodiment, when the kth high frequency component standard deviation σ(Dⱼₖ) is greater than the first high frequency component standard deviation σ(Dⱼ₁), it indicates that an internal impedance of the kth battery cell in the second frequency band is greater than an internal impedance of the first battery cell in the second frequency band. That is, even though the same current profile is applied to the kth battery cell and the first battery cell, a voltage response or variation of the kth battery cell in the second frequency band is greater than a voltage response or variation of the first battery cell in the second frequency band.

In FIG. 1, the second statistics processing unit 140 generates a standard deviation σ(σ_{V}) of cell voltage standard deviations, a standard deviation σ(σ_{Aj}) of low frequency component standard deviations, and a standard deviation σ(σ_{Dj}) of high frequency component standard deviations by receiving the first to nth cell voltage standard deviations σ(V₁), σ(V₂), σ(V₃), . . . , σ(Vₙ), the first to nth low frequency component standard deviations σ(Aⱼ₁), σ(Aⱼ₂), σ(Aⱼ₃), . . . , σ(Aⱼₙ), and the first to nth high frequency component standard deviations σ(Dⱼ₁), σ(Dⱼ₂), σ(Dⱼ₃), . . . , σ(Dⱼₙ) and performing respective (second order) standard deviation calculations thereon.

In one embodiment, the second statistics processing unit 140 generates the standard deviation σ(σ_{V}) of cell voltage standard deviations by calculating a standard deviation of the first to nth cell voltage standard deviations σ(V₁), σ(V₂), σ(V₃), . . . , σ(Vₙ) generated by the first statistics processing unit 130. A small value of the standard deviation σ(σ_{V}) of cell voltage standard deviations indicates that a difference between voltage variations of the battery cells in the battery pack P1 over the set or predetermined period of time is small, i.e., that a voltage variation balance among the battery cells in the battery pack P1 is maintained. For example, in one embodiment, when the battery pack P1 is changed from a charging state to a discharging state, a small value of the standard deviation σ(σ_{V}) of cell voltage standard deviations indicates that voltages of the battery cells in the battery pack P1 vary with a constant or near constant potential.

On the contrary, a large value of the standard deviation σ(σ_{V}) of cell voltage standard deviations indicates that a difference between voltage variations of the battery cells in the battery pack P1 over the set or predetermined period of time is large, i.e., that a voltage variation imbalance among the battery cells in the battery pack P1 is large. For example, in one embodiment, when the battery pack P1 is changed from a charging state to a discharging state, a large value of the standard deviation σ(σ_{V}) of cell voltage standard deviations indicates that voltages of the battery cells in the battery pack P1 vary differently, e.g., when a set or predetermined current file is applied, a cell voltage of the first battery cell decreases by 0.5 V while a cell voltage of the second battery cell decreases by 0.1 V.

In one embodiment, the second statistics processing unit 140 generates the standard deviation σ(σ_{Aj}) of low frequency component standard deviations by calculating a standard deviation of the first to nth low frequency component standard deviations σ(Aⱼ₁), σ(Aⱼ₂), σ(Aⱼ₃), . . . , σ(Aⱼₙ) generated by the first statistics processing unit 130. In addition, the second statistics processing unit 140 generates the standard deviation σ(σ_{Dj}) of high frequency component standard deviations by calculating a standard deviation of the first to nth high frequency component standard deviations σ(Dⱼ₁), (Dⱼ₂), σ(Dⱼ₃), . . . , σ(Dⱼₙ) generated by the first statistics processing unit 130. In FIG. 1, the second statistics processing unit 140 provides the standard deviation σ(σ_{V}) of cell voltage standard deviations, the standard deviation σ(σ_{Aj}) of low frequency component standard deviations, and the standard deviation σ(σ_{Dj}) of high frequency component standard deviations to the SOH prediction unit 170.

In addition, the second statistics processing unit 140 generates a standard deviation σ₀(σ_{V}) of initial cell voltage standard deviations, a standard deviation σ₀(σ_{Aj}) of initial low frequency component standard deviations, and a standard deviation σ₀(σ_{Dj}) of initial high frequency component standard deviations based on first to nth cell voltage standard deviations σ(V₁), σ(V₂), σ(V₃), . . . , σ(Vₙ), first to nth low frequency component standard deviations σ(Aⱼ₁), σ(Aⱼ₂), σ(Aⱼ₃), . . . , σ(Aⱼₙ), and first to nth high frequency component standard deviations σ(Dⱼ₁), σ(Dⱼ₂), σ(Dⱼ₃), . . . , σ(Dⱼₙ) received from the first statistics processing unit 130 during an initial time when the battery pack P1 initially functions. In FIG. 1, the second statistics processing unit 140 provides the standard deviation σ₀(σ_{V}) of initial cell voltage standard deviations, the standard deviation σ₀(σ_{Aj}) of initial low frequency component standard deviations, and the standard deviation σ₀(σ_{Dj}) of initial high frequency component standard deviations generated during the initial time to the initial value storage unit 150.

In one embodiment, the initial value storage unit 150 stores the standard deviation σ₀(σ_{V}) of initial cell voltage standard deviations, the standard deviation σ₀(σ_{Aj}) of initial low frequency component standard deviations, and the standard deviation a₀(σ_{Dj}) of initial high frequency component standard deviations, and provides the standard deviation σ₀(σ_{V}) of initial cell voltage standard deviations, the standard deviation σ₀(σ_{Aj}) of initial low frequency component standard deviations, and the standard deviation σ₀(σ_{Dj}) of initial high frequency component standard deviations to the SOH prediction unit 170 when they are used to predict an SOH of the battery pack P1.

In FIG. 1, the coefficient storage unit 160 stores coefficients α, β, and γ that are used by the SOH prediction unit 170 to perform SOH prediction, and provides the coefficients α, β, and γ to the SOH prediction unit 170 for the SOH prediction of the battery pack P1. The coefficient α is used to predict a cell voltage base SOH(SOH_{V}) of the battery pack P1 based on the standard deviation σ(σ_{V}) of cell voltage standard deviations. The coefficient β is used to predict a low frequency component base SOH(SOH_{Aj}) of the battery pack P1 based on the standard deviation σ(σ_{Aj}) of low frequency component standard deviations. The coefficient γ is used to predict a high frequency component base SOH(SOH_{Dj}) of the battery pack P1 based on the standard deviation σ(σ_{Dj}) of high frequency component standard deviations.

In one embodiment, the coefficients α, β, and γ vary according to electrical characteristics and an arrangement structure of the battery cells in the battery pack P1. In one embodiment, an operator determines the coefficients α, β, and γ in advance according to the battery pack P1. In one embodiment, the coefficients α, β, and γ are determined by an algorithm of the whole system including the battery pack P1. A process of determining the coefficients α, β, and γ by the algorithm will be described in more detail below.

In one embodiment, the SOH prediction unit 170 receives the standard deviation σ(σ_{V}) of cell voltage standard deviations, the standard deviation σ(σ_{Aj}) of low frequency component standard deviations, and the standard deviation σ(σ_{Dj}) of high frequency component standard deviations from the second statistics processing unit 140. The standard deviation σ(σ_{V}) of cell voltage standard deviations, the standard deviation σ(σ_{Aj}) of low frequency component standard deviations, and the standard deviation σ(σ_{Dj}) of high frequency component standard deviations are generated based on cell voltage data collected for a set or predetermined data collection period, and are used to predict an SOH of the battery pack P1. In addition, in one embodiment, the SOH prediction unit 170 receives the standard deviation σ₀(σ_{V}) of initial cell voltage standard deviations, the standard deviation σ₀(σ_{Aj}) of initial low frequency component standard deviations, and the standard deviation σ₀(σ_{Dj}) of initial high frequency component standard deviations from the initial value storage unit 150, and receives the coefficients α, β, and γ from the coefficient storage unit 160.

In one embodiment, the SOH prediction unit 170 calculates the cell voltage base SOH(SOH_{V}) based on the standard deviation σ(σ_{V}) of cell voltage standard deviations, the standard deviation σ₀(σ_{V}) of initial cell voltage standard deviations, and the coefficient α. In addition, in one embodiment, the SOH prediction unit 170 calculates the low frequency component base SOH(SOH_{Aj}) based on the standard deviation σ(σ_{Aj}) of low frequency component standard deviations, the standard deviation σ₀(σ_{Aj}) of initial low frequency component standard deviations, and the coefficient β. Further, in one embodiment, the SOH prediction unit 170 calculates the high frequency component base SOH(SOH_{Dj}) based on the standard deviation σ(σ_{Dj}) of high frequency component standard deviations, the standard deviation σ₀(σ_{Dj}) of initial high frequency component standard deviations, and the coefficient γ.

In one embodiment, the SOH prediction unit 170 predicts an SOH of the battery pack P1 by calculating a final SOH(SOH) based on the cell voltage base SOH(SOH_{V}), the low frequency component base SOH(SOH_{Aj}), and the high frequency component base SOH(SOH_{Dj}). In one embodiment, the SOH prediction unit 170 outputs the SOH(SOH). In one embodiment, the SOH(SOH) is provided to the BMS in the battery system or the general controller in the energy storage system.

Calculation by the SOH prediction unit 170 according to an embodiment will now be described in detail. First, the discrete wavelet transform (DWT) is described. A wavelet transform is used to decompose a source signal x(t) by transforming a magnitude and a horizontal position of a circular wavelet function. A continuous wavelet transform (CWT) is defined by Equation 1 below.

$${W}^{f} ( a , b ) = < x ( t ) , {ψ}_{a , b} ( t ) >= \frac{1}{\sqrt{a}} {\int }_{- ∞}^{∞} x ( t ) {ψ}^{*} ( \frac{t - b}{a} ) d t \qquad ( 1 )$$

In Equation 1, a and b are parameters respectively indicating a scale and a translation, ψ(t) denotes a wavelet analysis function, and ψ* denotes a complex conjugate function. A result of Equation 1 is a wavelet coefficient of the scale and translation parameters.

Substitution of a=2^{j} and b=k2^{j} into Equation 1 results in a DWT defined by Equation 2 below. In Equation 2, integers j and k are scale and translation variables, respectively.

$${W}^{f} ( j , k ) = < x ( t ) , {ψ}_{j , k} ( t ) >= \frac{1}{\sqrt{{2}^{j}}} {\int }_{- ∞}^{∞} x ( t ) {ψ}^{*} ( \frac{t - k {2}^{j}}{{2}^{j}} ) d t \qquad ( 2 )$$

In one-dimensional signal decomposition using wavelets, a scale function φ and a wavelet function ψ are used. The wavelet function ψ is used to obtain a detailed component Dⱼ from the source signal x(t), and the scale function φ is used to decompose an approximate component Aⱼ from the source signal x(t). FIG. 2 illustrates the scale function φ and the wavelet function ψ. The scale function φ and the wavelet function ψ shown in FIG. 2 are based on Daubechies 3 (dB3) wavelets.

In the DWT, in one embodiment, approximate information xₐ^{j}(t) and detailed information x_{d}^{j}(t) obtained at an arbitrary scale j from the source signal x(t) are represented by Equation 3 below.

$${x}_{a}^{j} ( t ) = {\sum }_{k} {a}_{j , k} {φ}_{k} ( {2}^{- j} t ) = {\sum }_{k} {a}_{j , k} {φ}_{j , k} ( t ) , k ε Z \\ {x}_{d}^{j} ( t ) = {\sum }_{k} {d}_{j , k} {ψ}_{k} ( {2}^{- j} t ) = {\sum }_{k} {d}_{j , k} {ψ}_{j , k} ( t ) , k ε Z \qquad ( 3 )$$

In Equation 3, a_{j,k} and d_{j,k} denote an approximate coefficient (scale coefficient) and a detailed coefficient (wavelet coefficient), respectively.

In one embodiment, the source signal x(t) is represented by Equation 4 below using the approximate information xₐ^{j}(t) and the detailed information x_{d}^{j}(t).

$$x ( t ) = {\sum }_{k} {a}_{j , k} {2}^{- \frac{j}{2}} φ ( {2}^{- j} t - k ) + {\sum }_{j = 1} {\sum }_{k} {d}_{j , k} {2}^{- \frac{j}{2}} ψ ( {2}^{- j} t - k ) \qquad ( 4 )$$

In addition, in one embodiment, a_{j,k} and d_{j,k} are represented by Equation 5 below using the scale function φ and the wavelet function ψ, respectively.

$${a}_{j , k} = < x ( t ) , {φ}_{j , k} ( t ) >= {\int }_{R} x ( t ) {2}^{- \frac{j}{2}} {φ}^{*} ( {2}^{- j} t - k ) d t \\ {d}_{j , k} = < x ( t ) , {ψ}_{j , k} ( t ) >= {\int }_{R} x ( t ) {2}^{- \frac{j}{2}} {ψ}^{*} ( {2}^{- j} t - k ) d t \qquad ( 5 )$$

The approximate information xₐ^{j}(t) corresponds to a scale function φ_{j,k}(t) of a low frequency component, and the detailed information x_{d}^{j}(t) corresponds to a wavelet function ψ_{j,k}(t) of a high frequency component. In one embodiment, when the approximate information xₐ^{j}(t) and the detailed information x_{d}^{j}(t) are simplified to A and D, respectively, the source signal x(t) is represented by Equation 6 below when multi-resolution decomposition of the source signal x(t) is performed up to an nth level.

x(t)=Aₙ+D₁+D₂+ . . . +Dₙ₋₁+Dₙ (6)

By adding detailed information Dₙ to approximate information Aₙ, approximate information Aₙ₋₁ having a one-level higher resolution is obtained. That is, Aₙ₋₁=Aₙ+Dₙ. In addition, the source signal x(t) may be represented by A₁+D₁.

FIG. 3 is a schematic block diagram for describing a DWT in terms of filtering.

In the DWT of FIG. 3, data x(n) is decomposed into approximate information A corresponding to a low frequency component and detailed information D corresponding to a high frequency component. In FIG. 3, a low-pass filter (LPF) is used to extract the approximate information A from the data x(n). In addition, a high-pass filter (HPF) is used to extract the detailed information D from the data x(n). In one embodiment, the LPF and the HPF are not actual filters that are implemented physically or by a circuit, but are instead implemented by data processing.

FIG. 4 illustrates coefficients of the LPF and the HPF.

For example, as shown in FIG. 4, coefficients of the LPF are {0.0352, −0.0854, −0.1350, 0.4599, 0.8069, 0.3327}, and coefficients of the HPF are {−0.3327, 0.8069, −0.4599, −0.1350, 0.0854, 0.0352}.

FIG. 5 is a block diagram for describing a process of decomposing voltage data V(x) by a multi-resolution analysis of a DWT. Although it is shown in FIG. 5 that a DWT is repeatedly performed five times, the number of repetitions of a DWT is not limited thereto. That is, in respective other embodiments, a DWT is performed only once or more than five times. As described above, in one embodiment, a DWT is performed using the LPF and the HPF.

In FIG. 5, the voltage data V(x) is decomposed into approximate voltage data A₁(x) of the first level and detailed voltage data D₁(x) of the first level. In one embodiment, the approximate voltage data A₁(x) of the first level is extracted using the LPF, and the detailed voltage data D₁(x) of the first level is extracted using the HPF.

Continuing in FIG. 5, the approximate voltage data A₁(x) of the first level is decomposed into approximate voltage data A₂(x) of the second level and detailed voltage data D₂(x) of the second level by a second DWT and down-sampling. Likewise, in FIG. 5, the approximate voltage data A₂(x) of the second level is decomposed into approximate voltage data A₃(x) of the third level and detailed voltage data D₃(x) of the third level by a third DWT and down-sampling. Further, in FIG. 5, the approximate voltage data A₃(x) of the third level is decomposed into approximate voltage data A₄(x) of the fourth level and detailed voltage data D₄(x) of the fourth level by a fourth DWT and down-sampling.

Continuing, in FIG. 5, the approximate voltage data A₄(x) of the fourth level is decomposed into approximate voltage data A₅(x) of the fifth level and detailed voltage data D₅(x) of the fifth level by a fifth DWT and down-sampling.

In one embodiment, the approximate voltage data A₅(x) of the fifth level and the detailed voltage data D₅(x) of the fifth level, which are extracted by performing discrete wavelet transform multi-resolution analysis on each of the first to nth cell voltage data V₁, V₂, V₃, Vₙ of the first to nth battery cells, are respectively provided to the first statistics processing unit 130 as the first to nth low frequency component data Aⱼ₁, Aⱼ₂, Aⱼ₃, . . . , Aⱼₙ of the jth level and the first to nth high frequency component data Dⱼ₁, Dⱼ₂, Dⱼ₃, . . . , Dⱼₙ of the jth level (where, in this case, j=5).

As shown in FIG. 5, the voltage data V(x) is represented using the approximate voltage data A₅(x) of the fifth level and the detailed voltage data D₁(x), D₂(x), D₃(x), D₄(x), D₅(x) of the first to fifth levels. In addition, approximate voltage data Aₙ₋₁(x) of an (n−1)th level is represented by a sum of approximate voltage data Aₙ(x) of the nth level and detailed voltage data Dₙ(x) of the nth level (for n=1, 2, 3, 4).

In the current example of FIG. 5, the voltage data V(x) is restored from the approximate voltage data A₅(x) of the fifth level and the detailed voltage data D₁(x), D₂(x), D₃(x), D₄(x), D₅(x) of the first to fifth levels. In one embodiment, this restoring process is referred to as an inverse DWT (IDWT).

As shown in FIG. 5, the repetition of a DWT causes an increase in a total amount of data because the voltage data V(x) is decomposed into approximate voltage data A(x) and detailed voltage data D(x). Thus, as shown in FIG. 5, down-sampling is performed after a DWT is performed.

In one embodiment, down-sampling involves selecting every other data (such as the even data or the odd data) of approximate voltage data generated by a previous DWT and removing non-selected data. FIG. 6 illustrates down-sampling. As shown in FIG. 6, n pieces of data are reduced to n/2 pieces of data by down-sampling.

FIG. 7 illustrates a frequency band of the approximate voltage data Aₙ(x) of the nth level and frequency bands of detailed voltage data D₁(x), D₂(x), . . . , Dₙ(x) of the first to nth levels.

In FIG. 7, the detailed voltage data D₁(x) of the first level is data of a frequency band that is less than a first frequency fₛ/2 and greater than a second frequency fₛ/4, and the detailed voltage data D₂(x) of the second level corresponds to data of a frequency band that is less than the second frequency fₛ/4 and greater than a third frequency fₛ/8. In addition, the detailed voltage data D₃(x) of the third level corresponds to data of a frequency band that is less than the third frequency fₛ/8 and greater than a fourth frequency fₛ/16. Continuing in this fashion, the detailed voltage data Dₙ(x) of the nth level corresponds to data of a frequency band that is less than an nth frequency fₛ/2ⁿ and greater than an (n+1)th frequency fₛ/2ⁿ⁺¹. In addition, the approximate voltage data Aₙ(x) of the nth level corresponds to data of a frequency band that is less than the (n+1)th frequency fₛ/2ⁿ⁺¹

A method of predicting an SOH of the battery pack P1 according to various embodiments of the present invention will now be described with respect to a detailed example.

In the example below, it is assumed that the battery pack P1 includes 14 battery cells. The battery pack P1 may consist of 14 battery cells connected in series. According to another example, the battery pack P1 may include 70 battery cells connected in series, wherein 14 of the 70 battery cells are selected to predict an SOH. In addition, it is assumed that discrete wavelet transform multi-resolution analysis is performed up to a fifth level.

FIG. 8A is a graph of cell voltage data V(x) of an arbitrary one of a plurality of battery cells included in the battery pack P1, and FIGS. 8B and 8C respectively illustrate graphs of low frequency component data A1(x) to A5(x) of first to fifth levels and high frequency component data D1(x) to D5(x) of the first to fifth levels, which are extracted from the cell voltage data V(x) through a multi-resolution analysis of a DWT.

Referring to FIG. 8A, a graph of the cell voltage data V(x) at a discrete time x over an interval of time t is illustrated. In the graph of FIG. 8A, the cell voltage data V(x) is data obtained by measuring a cell voltage over 2880 minutes, i.e., 48 hours. In FIG. 8A, since the cell voltage data V(x) is obtained by measuring a cell voltage of battery cells actually being used, the cell voltage increases due to charging and decreases due to discharging over 48 hours. In one embodiment, the cell voltage data V(x) is generated by the cell voltage detection unit 110. In further detail, in another embodiment, the cell voltage data V(x) is generated by the BMS in the battery system.

FIG. 8B illustrates graphs of low frequency component data A1(x) to A5(x) of the first to fifth levels, which are extracted by performing discrete wavelet transform multi-resolution analysis on the cell voltage data V(x) shown in FIG. 8A. In addition, FIG. 8C illustrates graphs of high frequency component data D1(x) to D5(x) of the first to fifth levels, which are extracted by performing discrete wavelet transform multi-resolution analysis on the cell voltage data V(x) shown in FIG. 8A.

FIG. 9A is a graph of cell voltage data V of the 14 battery cells included in the battery pack P1.

Referring to FIG. 9A, first to fourteenth cell voltage data V₁, V₂, V₃, . . . , V₁₄ of the first to fourteenth battery cells are shown without being distinguished from each other. The first to fourteenth cell voltage data V₁, V₂, V₃, . . . , V₁₄ are collected for the first to fourteenth battery cells, respectively. In one embodiment, the first to fourteenth cell voltage data V₁, V₂, V₃, . . . , V₁₄ are collected by the cell voltage detection unit 110.

In one embodiment, the first to fourteenth cell voltage data V₁, V₂, V₃, . . . , V₁₄ are provided to the DWT unit 120 and the first statistics processing unit 130, and the first statistics processing unit 130 generates first to fourteenth cell voltage standard deviations σ(V₁), σ(V₂), σ(V₃), . . . , σ(V₁₄) by calculating a standard deviation for each of the first to fourteenth cell voltage data V₁, V₂, V₃, . . . , V₁₄. In one embodiment, the first to fourteenth cell voltage standard deviations σ(V₁), σ(V₂), σ(V₃), . . . , σ(V₁₄) are calculated as shown in Table 1.

TABLE 1

| | | | | | |
|---|---|---|---|---|---|
| σ(V₁) | 0.035099 | σ(V₂) | 0.034938 | σ(V₃) | 0.034994 |
| σ(V₄) | 0.034610 | σ(V₅) | 0.034659 | σ(V₆) | 0.034021 |
| σ(V₇) | 0.033722 | σ(V₈) | 0.035657 | σ(V₉) | 0.035878 |
| σ(V₁₀) | 0.032827 | σ(V₁₁) | 0.035987 | σ(V₁₂) | 0.035743 |
| σ(V₁₃) | 0.036270 | σ(V₁₄) | 0.036108 | | |

In one embodiment, the second statistics processing unit 140 generates a standard deviation σ(σ_{V}) of cell voltage standard deviations by receiving the first to fourteenth cell voltage standard deviations σ(V₁), σ(V₂), σ(V₃), . . . , σ(V₁₄) calculated by the first statistics processing unit 130, and performing a standard deviation calculation of the received first to fourteenth cell voltage standard deviations σ(V₁), σ(V₂), σ(V₃), . . . , σ(V₁₄). For example, the calculated standard deviation σ(σ_{V}) of cell voltage standard deviations shown in Table 1 is 0.001005.

FIG. 9B is a graph of low frequency component data A5 of the fifth level, which is extracted by performing discrete wavelet transform multi-resolution analysis on each of the cell voltage data V of FIG. 9A.

Referring to FIG. 9B, first to fourteenth low frequency component data A5₁, A5₂, A5₃, . . . , A5₁₄ of the fifth level generated from the first to fourteenth cell voltage data V₁, V₂, V₃, . . . , V₁₄ of the first to fourteenth battery cells are shown without being distinguished from each other. The first to fourteenth low frequency component data A5₁, A5₂, A5₃, . . . , A5₁₄ of the fifth level are respectively extracted from the first to fourteenth cell voltage data V₁, V₂, V₃, . . . , V₁₄ of the first to fourteenth battery cells.

In one embodiment, the DWT unit 120 generates the first to fourteenth low frequency component data A5₁, A5₂, A5₃, . . . , A5₁₄ of the fifth level by performing discrete wavelet transform multi-resolution analysis on the first to fourteenth cell voltage data V₁, V₂, V₃, . . . , V₁₄ of the first to fourteenth battery cells. In one embodiment, the first statistics processing unit 130 generates first to fourteenth low frequency component standard deviations σ(A5₁), σ(A5₂), σ(A5₃), . . . , σ(A5₁₄) by receiving the first to fourteenth low frequency component data A5₁, A5₂, A5₃, . . . , A5₁₄ of the fifth level, and calculating a standard deviation for each of the first to fourteenth low frequency component data A5₁, A5₂, A5₃, . . . , A5₁₄ of the fifth level. In one embodiment, the first to fourteenth low frequency component standard deviations σ(A5₁), σ(A5₂), σ(A5₃), . . . , σ(A5₁₄) are calculated as shown in Table 2 below.

TABLE 2

| | | | | | |
|---|---|---|---|---|---|
| σ(A5₁) | 0.034929 | σ(A5₂) | 0.034770 | σ(A5₃) | 0.034834 |
| σ(A5₄) | 0.034443 | σ(A5₅) | 0.034483 | σ(A5₆) | 0.033868 |
| σ(A5₇) | 0.033586 | σ(A5₈) | 0.035509 | σ(A5₉) | 0.035730 |
| σ(A5₁₀) | 0.032684 | σ(A5₁₁) | 0.035844 | σ(A5₁₂) | 0.035601 |
| σ(A5₁₃) | 0.036102 | σ(A5₁₄) | 0.035945 | | |

In one embodiment, the second statistics processing unit 140 generates a standard deviation σ(σ_{A5}) of low frequency component standard deviations by receiving the first to fourteenth low frequency component standard deviations σ(A5₁), σ(A5₂), σ(A5₃), . . . , σ(A5₁₄) calculated by the first statistics processing unit 130, and performing a standard deviation calculation of the first to fourteenth low frequency component standard deviations σ(A5₁), σ(A5₂), σ(A5₃), . . . , σ(A5₁₄). For example, the calculated standard deviation σ(σ_{A5}) of low frequency component standard deviations shown in Table 2 is 0.001003.

FIG. 9C is a graph of high frequency component data D5 of the fifth level, which is extracted by performing discrete wavelet transform multi-resolution analysis on each of the cell voltage data V of FIG. 9A.

Referring to FIG. 9C, first to fourteenth high frequency component data D5₁, D5₂, D5₃, . . . , D5₁₄ of the fifth level generated from the first to fourteenth cell voltage data V₁, V₂, V₃, . . . , V₁₄ of the first to fourteenth battery cells are shown without being distinguished from each other. The first to fourteenth high frequency component data D5₁, D5₂, D5₃, . . . , D5₁₄ of the fifth level are respectively extracted from the first to fourteenth cell voltage data V₁, V₂, V₃, . . . , V₁₄ of the first to fourteenth battery cells.

In one embodiment, the DWT unit 120 generates the first to fourteenth high frequency component data D5₁, D5₂, D5₃, . . . , D5₁₄ of the fifth level by performing discrete wavelet transform multi-resolution analysis on the first to fourteenth cell voltage data V₁, V₂, V₃, . . . , V₁₄ of the first to fourteenth battery cells. In one embodiment, the first statistics processing unit 130 generates first to fourteenth high frequency component standard deviations σ(D5₁), σ(D5₂), σ(D5₃), . . . , σ(D5₁₄) by receiving the first to fourteenth high frequency component data D5₁, D5₂, D5₃, . . . , D5₁₄ of the fifth level, and calculating a standard deviation for each of the first to fourteenth high frequency component data D5₁, D5₂, D5₃, . . . , D5₁₄ of the fifth level. In one embodiment, the first to fourteenth high frequency component standard deviations σ(D5₁), σ(D5₂), σ(D5₃), . . . , σ(D5₁₄) are calculated as shown in Table 3 below.

TABLE 3

| | | | | | |
|---|---|---|---|---|---|
| σ(D5₁) | 0.002436 | σ(D5₂) | 0.002455 | σ(D5₃) | 0.002420 |
| σ(D5₄) | 0.002408 | σ(D5₅) | 0.002464 | σ(D5₆) | 0.002226 |
| σ(D5₇) | 0.002054 | σ(D5₈) | 0.002262 | σ(D5₉) | 0.002199 |
| σ(D5₁₀) | 0.002022 | σ(D5₁₁) | 0.002222 | σ(D5₁₂) | 0.002194 |
| σ(D5₁₃) | 0.002502 | σ(D5₁₄) | 0.002441 | | |

In one embodiment, the second statistics processing unit 140 generates a standard deviation σ(σ_{D5}) of high frequency component standard deviations by receiving the first to fourteenth high frequency component standard deviations σ(D5₁), σ(D5₂), σ(D5₃), . . . , σ(D5₁₄) calculated by the first statistics processing unit 130, and performing a standard deviation calculation of the first to fourteenth high frequency component standard deviations σ(D5₁), σ(D5₂), σ(D5₃), . . . , σ(D5₁₄). For example, the calculated standard deviation σ(σ_{D5}) of high frequency component standard deviations shown in Table 3 is 1.587865×10⁻⁴.

In one embodiment, the standard deviation σ₀(σ_{V}) of initial cell voltage standard deviations, the standard deviation σ₀(σ_{Aj}) of initial low frequency component standard devia tions, and the standard deviation σ₀(σ_{Dj}) of initial high frequency component standard deviations are also generated using the same method as described above. However, in this case, there is a difference in that the first to fourteenth cell voltage data V₁, V₂, V₃, . . . , V₁₄ are collected from an initial time when the battery pack P1 starts.

In addition, the coefficients α, β, and γ vary according to factors such as the number of battery cells included in the battery pack P1, the number of cell voltage data, an arrangement structure of the battery cells, and the like.

In one embodiment, the SOH prediction unit 170 receives the standard deviation σ(σ_{V}) of cell voltage standard deviations, the standard deviation σ(σ_{Aj}) of low frequency component standard deviations, and the standard deviation σ(σ_{Dj}) of high frequency component standard deviations from the second statistics processing unit 140, receives the standard deviation σ₀(σ_{V}) of initial cell voltage standard deviations, the standard deviation σ₀(σ_{Aj}) of initial low frequency component standard deviations, and the standard deviation σ₀(σ_{Dj}) of initial high frequency component standard deviations from the initial value storage unit 150, receives the coefficients α, β, and γ from the coefficient storage unit 160, and predicts an SOH of the battery pack P1 based on the received values.

In one embodiment, the SOH prediction unit 170 calculates the cell voltage base SOH(SOH_{V}) based on the standard deviation σ(σ_{V}) of cell voltage standard deviations, the standard deviation σ₀(σ_{V}) of initial cell voltage standard deviations, and the coefficient α. In one embodiment, a formula for calculating the cell voltage base SOH(SOH_{V}) is represented by Equation 7 below.

$$\begin{matrix}{SOH}_{V} = 1 - \frac{\vert σ ( {σ}_{V} ) - {σ}_{0} ( {σ}_{V} ) \vert}{{ασ}_{0} ( {σ}_{V} )} & 0 \leq {SOH}_{V} \leq 1\end{matrix} \\ \begin{matrix}{SOH}_{V} = 0 & if σ ( {σ}_{V} ) = ( α + 1 ) {σ}_{0} ( {σ}_{V} ) \\ {SOH}_{V} = 1 & if σ ( {σ}_{V} ) = {σ}_{0} ( {σ}_{V} )\end{matrix} \qquad ( 7 )$$

In Equation 7, the cell voltage base SOH(SOH_{V}) having a value of 1 indicates a fresh state of the battery pack P1, and the cell voltage base SOH(SOH_{V}) having a value of 0 indicates an aged state of the battery pack P1. In addition, in Equation 7, the cell voltage base SOH(SOH_{V}) is calculated based on a difference between the standard deviation σ(σ_{V}) of cell voltage standard deviations and the standard deviation σ₀(σ_{V}) of initial cell voltage standard deviations, and a value obtained by multiplying the standard deviation σ₀(σ_{V}) of initial cell voltage standard deviations by the coefficient α. As the standard deviation σ(σ_{V}) of cell voltage standard deviations becomes greater than the standard deviation σ₀(σ_{V}) of initial cell voltage standard deviations, the cell voltage base SOH(SOH_{V}) decreases more, indicating that the battery pack P1 is aging.

In one embodiment, the SOH prediction unit 170 calculates the low frequency component base SOH(SOH_{Aj}) based on the standard deviation σ(σ_{Aj}) of low frequency component standard deviations, the standard deviation σ₀(σ_{Aj}) of initial low frequency component standard deviations, and the coefficient β. In one embodiment, a formula for calculating the low frequency component base SOH(SOH_{Aj}) is represented by Equation 8 below.

$$\begin{matrix}{SOH}_{Aj} = 1 - \frac{\vert σ ( {σ}_{Aj} ) - {σ}_{0} ( {σ}_{Aj} ) \vert}{{βσ}_{0} ( {σ}_{Aj} )} & 0 \leq {SOH}_{Aj} \leq 1\end{matrix} \\ \begin{matrix}{SOH}_{Aj} = 0 & if σ ( {σ}_{Aj} ) = ( β + 1 ) {σ}_{0} ( {σ}_{Aj} ) \\ {SOH}_{Aj} = 1 & if σ ( {σ}_{Aj} ) = {σ}_{0} ( {σ}_{Aj} )\end{matrix} \qquad ( 8 )$$

In Equation 8, the low frequency component base SOH(SOH_{Aj}) having a value of 1 indicates a fresh state of the battery pack P1, and the low frequency component base SOH(SOH_{Aj}) having a value of 0 indicates an aged state of the battery pack P1. In addition, in Equation 8, the low frequency component base SOH(SOH_{Aj}) is calculated based on a difference between the standard deviation σ(σ_{Aj}) of low frequency component standard deviations and the standard deviation σ₀(σ_{Aj}) of initial low frequency component standard deviations, and a value obtained by multiplying the standard deviation σ₀(σ_{Aj}) of initial low frequency component standard deviations by the coefficient β. As the standard deviation σ(σ_{Aj}) of low frequency component standard deviations becomes greater than the standard deviation σ₀(σ_{Aj}) of initial low frequency component standard deviations, the low frequency component base SOH(SOH_{Aj}) decreases more, indicating that the battery pack P1 is aging.

In one embodiment, the SOH prediction unit 170 calculates the high frequency component base SOH(SOH_{Dj}) based on the standard deviation σ(σ_{Dj}) of high frequency component standard deviations, the standard deviation σ₀(σ_{Dj}) of initial high frequency component standard deviations, and the coefficient γ. In one embodiment, a formula for calculating the high frequency component base SOH(SOH_{Dj}) is represented by Equation 9 below.

$$\begin{matrix}{SOH}_{Dj} = 1 - \frac{\vert σ ( {σ}_{Dj} ) - {σ}_{0} ( {σ}_{Dj} ) \vert}{{γσ}_{0} ( {σ}_{Dj} )} & 0 \leq {SOH}_{Dj} \leq 1\end{matrix} \\ \begin{matrix}{SOH}_{Dj} = 0 & if σ ( {σ}_{Dj} ) = ( γ + 1 ) {σ}_{0} ( {σ}_{Dj} ) \\ {SOH}_{Dj} = 1 & if σ ( {σ}_{Dj} ) = {σ}_{0} ( {σ}_{Dj} )\end{matrix} \qquad ( 9 )$$

In Equation 9, the high frequency component base SOH(SOH_{Dj}) is calculated based on a difference between the standard deviation σ(σ_{Dj}) of high frequency component standard deviations and the standard deviation σ₀(σ_{Dj}) of initial high frequency component standard deviations, and a value obtained by multiplying the standard deviation σ₀(σ_{Dj}) of initial high frequency component standard deviations by the coefficient γ. As the standard deviation σ(σ_{Dj}) of high frequency component standard deviations becomes greater than the standard deviation σ₀(σ_{Dj}) of initial high frequency component standard deviations, the high frequency component base SOH(SOH_{Dj}) decreases more, indicating that the battery pack P1 is aging.

In one embodiment, the SOH prediction unit 170 predicts an SOH of the battery pack P1 by calculating a final SOH(SOH) based on the cell voltage base SOH(SOH_{V}), the low frequency component base SOH(SOH_{Aj}), and the high frequency component base SOH(SOH_{Dj}). In one embodiment, a formula for calculating the final SOH(SOH) is represented by, for example, Equation 10 below.

$$\begin{matrix}SOH = \frac{{SOH}_{V} + {SOH}_{Aj} + {SOH}_{Dj}}{3} & 0 \leq SOH \leq 1\end{matrix} \qquad ( 10 )$$

According to the example shown in Equation 10, the final SOH(SOH) is an arithmetic mean of the cell voltage base SOH(SOH_{V}), the low frequency component base SOH(SOH_{Aj}), and the high frequency component base SOH(SOH_{Dj}). However, the present invention is not limited to this example, and in other embodiments, the final SOH(SOH) is calculated as a weighted mean using first to third weight coefficients ω₁, ω₂, and ω₃.

For example, in some embodiments, the final SOH(SOH) is determined by a sum of the product of the first weight coefficient ω₁ and the cell voltage base SOH(SOH_{V}), the product of the second weight coefficient ω₂ and the low frequency component base SOH(SOH_{Aj}), and the product of the third weight coefficient ω₃ and the high frequency component base SOH(SOH_{Dj}), wherein each of the first to third weight coefficients ω₁, ω₂, and ω₃ is greater than or equal to 0 and less than 1, and a sum of the third weight coefficients ω₁, ω₂, and ω₃ is 1.

For example, in one embodiment, the first weight coefficient ω₁ is 0.2, the second weight coefficient ω₂ is 0.3, and the third weight coefficient ω₃ is 0.5. As another example, in one embodiment, the first weight coefficient ω₁ is 0, the second weight coefficient ω₂ is 0.6, and the third weight coefficient ω₃ is 0.4.

A method of determining values of the coefficients α, β, and γ needed to predict an SOH of the battery pack P1 according to various embodiments of the present invention will now be described with respect to an example.

In the example below, it is assumed that second to tenth battery packs P2 to P10 each have the same configuration as the battery pack P1 (hereinafter, first battery pack P1). The first to tenth battery packs P1 to P10 include a same number of battery cells and have a same arrangement structure of the battery cells. However, the first to tenth battery packs P1 to P10 are separate battery packs. For example, in one embodiment, some of the first to tenth battery packs P1 to P10 are connected in series to have a higher level output voltage, and the other battery packs are connected to another power system or connected in parallel. That is, in some embodiments, current profiles applied to the first to tenth battery packs P1 to P10 are different from each other.

As described above, FIG. 9A is a graph of cell voltage data V of the 14 battery cells included in the first battery pack P1, FIG. 9B is a graph of low frequency component data A5 of the fifth level, which is extracted by performing discrete wavelet transform multi-resolution analysis on each of the cell voltage data V of FIG. 9A, and FIG. 9C is a graph of high frequency component data D5 of the fifth level, which is extracted by performing discrete wavelet transform multi-resolution analysis on each of the cell voltage data V of FIG. 9A.

The standard deviation σ(σ_{V}) of cell voltage standard deviations, which is calculated for the first battery pack P1, is 0.001005, the standard deviation σ(σ_{A5}) of low frequency component standard deviations, which is calculated for the first battery pack P1, is 0.001003, and the standard deviation σ(σ_{D5}) of high frequency component standard deviations, which is calculated for the first battery pack P1, is 1.587865×10⁻⁴.

FIGS. 10A to 10I are graphs showing cell voltage data V of 14 battery cells included in the second to tenth battery packs P2 to P10, respectively, as well as graphs showing low frequency component data A5 of the fifth level and graphs showing high frequency component data D5 of the fifth level for these battery packs.

For the second to tenth battery packs P2 to P10, in the same manner as the first battery pack P1, in one embodiment, cell voltage data V is also generated using the cell voltage detection unit 110, and the DWT unit 120 also extracts low frequency component data A5 of the fifth level and high frequency component data D5 of the fifth level based on the cell voltage data V. Likewise, in one embodiment, the first statistics processing unit 130 and the second statistics processing unit 140 also calculate a standard deviation σ(σ_{V}) of cell voltage standard deviations, a standard deviation σ(σ_{A5}) of low frequency component standard deviations, and a standard deviation σ(σ_{D5}) of high frequency component standard deviations for each of the second to tenth battery packs P2 to P10.

The standard deviation σ(σ_{V}) of cell voltage standard deviations, the standard deviation σ(σ_{A5}) of low frequency component standard deviations, and the standard deviation σ(σ_{D5}) of high frequency component standard deviations for each of the first to tenth battery packs P1 to P10 are as shown in Table 4 below.

TABLE 4

| Pack | σ(σ_{V}) | σ(σ_{A5}) | σ(σ_{D5}) |
|---|---|---|---|
| P1 | 10.05 × 10⁻⁴ | 10.03 × 10⁻⁴ | 15.88 × 10⁻⁵ |
| P2 | 3.83 × 10⁻⁴ | 3.96 × 10⁻⁴ | 3.80 × 10⁻⁵ |
| P3 | 22.86 × 10⁻⁴ | 23.15 × 10⁻⁴ | 13.71 × 10⁻⁵ |
| P4 | 35.74 × 10⁻⁴ | 36.15 × 10⁻⁴ | 35.53 × 10⁻⁵ |
| P5 | 6.06 × 10⁻⁴ | 6.02 × 10⁻⁴ | 6.24 × 10⁻⁵ |
| P6 | 20.43 × 10⁻⁴ | 20.58 × 10⁻⁴ | 13.03 × 10⁻⁵ |
| P7 | 2.02 × 10⁻⁴ | 2.03 × 10⁻⁴ | 2.18 × 10⁻⁵ |
| P8 | 8.11 × 10⁻⁴ | 8.22 × 10⁻⁴ | 8.76 × 10⁻⁵ |
| P9 | 7.04 × 10⁻⁴ | 6.93 × 10⁻⁴ | 7.13 × 10⁻⁵ |
| P10 | 5.01 × 10⁻⁴ | 4.99 × 10⁻⁴ | 4.90 × 10⁻⁵ |

In one embodiment, the coefficient α is determined from values of the standard deviations σ(σ_{V}) of cell voltage standard deviations for the first to tenth battery packs P1 to P10. For example, in one embodiment, the coefficient α is determined as a ratio of a maximum value to a minimum value of the standard deviations σ(σ_{V}) of cell voltage standard deviations for the first to tenth battery packs P1 to P10.

Likewise, in one embodiment, the coefficient β is determined from values of the standard deviations σ(σ_{A5}) of low frequency component standard deviations for the first to tenth battery packs P1 to P10. For example, in one embodiment, the coefficient β is determined as a ratio of a maximum value to a minimum value of the standard deviations σ(σ_{A5}) of low frequency component standard deviations for the first to tenth battery packs P1 to P10.

In addition, in one embodiment, the coefficient γ is determined from values of the standard deviations σ(σ_{D5}) of high frequency component standard deviations for the first to tenth battery packs P1 to P10. For example, in one embodiment, the coefficient γ is determined as a ratio of a maximum value to a minimum value of the standard deviations σ(σ_{D5}) of high frequency component standard deviations for the first to tenth battery packs P1 to P10.

In one embodiment, a formula for calculating the coefficients α, β, and γ, and the values of the coefficients α, β, and γ in the example may be represented by Equation 11 below.

$$α = \frac{{σ}_{max} ( {σ}_{V} )}{{σ}_{min} ( {σ}_{V} )} = \frac{35.74 \times {10}^{- 4}}{2.03 \times {10}^{- 4}} = 17.61 \\ β = \frac{{σ}_{max} ( {σ}_{Aj} )}{{σ}_{min} ( {σ}_{Aj} )} = \frac{36.15 \times {10}^{- 4}}{2.03 \times {10}^{- 4}} = 17.81 \\ γ = \frac{{σ}_{max} ( {σ}_{Dj} )}{{σ}_{min} ( {σ}_{Dj} )} = \frac{35.53 \times {10}^{- 5}}{2.18 \times {10}^{- 5}} = 16.30 \qquad ( 11 )$$

In the example, the coefficient α is calculated to be 17.61, the coefficient β is calculated to be 17.81, and the coefficient γ is calculated to be 16.30.

In another embodiment of the present invention, an apparatus for predicting a state of health (SOH) of a battery pack includes a processor (such as a microprocessor) and a non-transitory storage device (such as a disk drive or a solid state drive). The storage device has instructions stored thereon that, when executed by the processor, causes the processor to perform any of the methods described herein.

According to an increase in the number of products that use a high voltage due to increased industrialization, a battery system is generally a battery pack instead of being a unit battery cell. A battery pack includes a plurality of battery cells connected in series, in parallel, or in a combination of series and parallel. In an ideal case, a voltage imbalance does not exist between the battery cells. However, in reality, a voltage imbalance does exist between the battery cells. The voltage imbalance between the battery cells increases as charging and discharging continues over a long period of time. Thus, in embodiments of the present invention, an aging of the battery pack is detected based on the voltage imbalance between the battery cells. According to one or more embodiments of the present invention, by predicting an SOH of a battery pack based on a voltage unbalance between battery cells, the SOH is predicted using a cell voltage easily obtainable without an additional configuration or circuit.

The various described embodiments of the present invention do not limit the scope of the present invention. For conciseness of the specification, the disclosure of conventional electronic configurations, control systems, software, and other functional aspects of the systems has been omitted. In addition, in corresponding embodiments, connections or connection members of lines between components shown in the drawings illustrate functional connections and/or physical or circuit connections, and in other corresponding embodiments, the connections or connection members are represented by replaceable or additional various functional connections, physical connections, or circuit connections in an actual apparatus. In addition, if there is no concrete mention of terms such as “requisite” or “important,” it is not necessarily a required component for application of the present invention.

The use of the term “said” or a similar directional term in the specification (in particular, in the claims) of the present invention corresponds to both the singular and the plural. In addition, when a range is disclosed in the specification of the present invention, embodiments to which individual values belonging to the range are applied are included (if there is no disclosure opposed to this), and this is the same as if each of the individual values forming the range is disclosed in the detailed description of the present invention. Finally, for steps forming the methods according to embodiments of the present invention, if an order is not clearly disclosed or, if there is no disclosure opposed to the clear order, the steps can be performed in any appropriate order. Embodiments of the present invention are not necessarily limited to the disclosed order of the steps.

The use of all illustrations or illustrative terms (for example, and so forth, etc.) in the present application is simply to describe embodiments of the present invention in detail, and the scope of the present invention is not limited to the illustrations or illustrative terms unless the scope is so limited by the claims. In addition, it will be understood by one of ordinary skill in the art that various modifications, combinations, and changes can be formed according to design conditions and factors within the scope of the attached claims or the equivalents.

While the present invention has been particularly shown and described with reference to embodiments thereof, it will be understood by those of ordinary skill in the art that various changes in form and details may be made therein without departing from the spirit and scope of the present invention as defined by the following claims, and equivalents thereof.

What is claimed is:

1. A method of predicting a state of health (SOH) of a battery pack, the method comprising:
obtaining at least one of charging voltage data or discharging voltage data for each of a plurality of selected cells of the battery pack;
wavelet transforming the at least one of charging voltage data or discharging voltage data to obtain low frequency component voltage data and high frequency component voltage data;
calculating respective standard deviations of at least two from among
the at least one of charging voltage data or discharging voltage data,
the low frequency component voltage data, and
the high frequency component voltage data; and
predicting the SOH of the battery pack based on the calculated standard deviations.

2. The method of claim 1, wherein the obtaining of the at least one of charging voltage data or discharging voltage data comprises:
detecting cell voltages of the selected cells with a cell voltage detection unit over a period of time to generate analog voltage values; and
converting the analog voltage values to digital voltage values to generate the at least one of charging voltage data or discharging voltage data.

3. The method of claim 2, wherein the cell voltage detection unit comprises a memory for storing the at least one of charging voltage data or discharging voltage data of the selected cells.

4. The method of claim 1, further comprising calculating a corresponding at least two from among
a charging and discharging SOH component from the calculated standard deviations of the at least one of charging voltage data or discharging voltage data,
a low frequency SOH component from the calculated standard deviations of the low frequency component voltage data, and
a high frequency SOH component from the calculated standard deviations of the high frequency component voltage data.

5. The method of claim 4, wherein the predicting of the SOH comprises calculating a weighted average of the calculated SOH components.

6. The method of claim 1, wherein the calculating of the respective standard deviations comprises calculating respective standard deviations of at least two from among
the at least one of charging voltage data or discharging voltage data for each of the selected cells,
the low frequency component voltage data for each of the selected cells, and
the high frequency component voltage data for each of the selected cells.

7. The method of claim 6, wherein the calculating of the respective standard deviations further comprises calculating respective standard deviations of a corresponding at least two from among
the calculated standard deviations of the at least one of charging voltage data or discharging voltage data for each of the selected cells,
the calculated standard deviations of the low frequency component voltage data for each of the selected cells, and
the calculated standard deviations of the high frequency component voltage data for each of the selected cells.

8. The method of claim 1, wherein the calculating of the respective standard deviations comprises:
calculating the respective standard deviations using voltage data corresponding to an initial period of time to generate initial calculated standard deviations; and
calculating the respective standard deviations using voltage data corresponding to a period of interest to generate interested calculated standard deviations.

9. The method of claim 8, wherein
the initial period of time comprises a period of time when the battery pack initially starts, and
the method further comprises storing the generated initial calculated standard deviations in a non-transitory storage device.

10. The method of claim 8, further comprising calculating a corresponding at least two from among
a charging and discharging SOH component from the initial calculated standard deviations and the interested calculated standard deviations of the at least one of charging voltage data or discharging voltage data,
a low frequency SOH component from the initial calculated standard deviations and the interested calculated standard deviations of the low frequency component voltage data, and
a high frequency SOH component from the initial calculated standard deviations and the interested calculated standard deviations of the high frequency component voltage data.

11. The method of claim 10, wherein the predicting of the SOH comprises calculating a weighted average of the calculated SOH components.

12. The method of claim 10, wherein a corresponding at least two from among
the calculating of the charging and discharging SOH component further comprises calculating the charging and discharging SOH component from a charging and discharging coefficient,
the calculating of the low frequency SOH component further comprises calculating the low frequency SOH component from a low frequency coefficient, and
the calculating of the high frequency SOH component further comprises calculating the high frequency SOH component from a high frequency coefficient.

13. The method of claim 12, wherein the coefficients are calculated from empirical data over a plurality of battery packs that are comparable to the battery pack.

14. The method of claim 1, wherein the wavelet transforming of the at least one of charging voltage data or discharging voltage data comprises:
converting the at least one of charging voltage data or discharging voltage data to first level low frequency component voltage data and first level high frequency component voltage data;
converting the first level low frequency component voltage data to second level low frequency component voltage data and second level high frequency component voltage data; and
converting the second level low frequency component voltage data to third level low frequency component voltage data and third level high frequency component voltage data.

15. The method of claim 1, wherein the wavelet transforming of the at least one of charging voltage data or discharging voltage data comprises performing multi-resolution analysis of a discrete wavelet transform of the at least one of charging voltage data or discharging voltage data for each of the selected cells.

16. The method of claim 15, wherein
the performing of the multi-resolution analysis comprises performing the multi-resolution analysis up to a jth level,
j is a natural number greater than 2,
the low frequency component voltage data is low frequency component voltage data of the jth level, and
the high frequency component voltage data is high frequency component voltage data of the jth level.

17. The method of claim 16, wherein
the low frequency component voltage data of the jth level corresponds to a first frequency band comprising frequencies lower than a first frequency, and
the high frequency component voltage data of the jth level corresponds to a second frequency band comprising frequencies higher than the first frequency and lower than double the first frequency.

18. An apparatus for predicting a state of health (SOH) of a battery pack, the apparatus comprising:
a processor; and
a non-transitory storage device,
wherein the storage device has instructions stored thereon that, when executed by the processor, causes the processor to perform the method of claim 1.

19. A state of health (SOH) prediction apparatus configured to predict an SOH of a battery pack coupled to the SOH prediction apparatus, the SOH prediction apparatus comprising:
a voltage detection unit configured to generate at least one of charging voltage data or discharging voltage data for each of a plurality of selected cells of the battery pack collected over a period of time;
a discrete wavelet transform (DWT) unit configured to extract low frequency component voltage data and high frequency component voltage data by performing multi-resolution analysis of the DWT for the at least one of charging voltage data or discharging voltage data;
a first statistics processing unit configured to generate respective first order standard deviations of at least two from among
the at least one of charging voltage data or discharging voltage data,
the low frequency component voltage data, and
the high frequency component voltage data;
a second statistics processing unit configured to generate respective second order standard deviations from the generated first order standard deviations; and
an SOH prediction unit configured to predict the SOH of the battery pack from the generated second order standard deviations.
